(19) United States
(12) Patent Application Publication
(10) Pub. No.: US 2008/0129663 A1
(43) Pub. Date: Jun. 5, 2008

(54) BACKLIGHT CONTROL APPARATUS, DISLAY DEVICE, AND METHOD FOR CONTROLLING BACKLIGHT OF DISPLAY DEVICE

(75) Inventor: Yuichi Honda, Fukaya-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/948,012

(22) Filed: Nov. 30, 2007

(30) Foreign Application Priority Data
Nov. 30, 2006 (JP) 2006-324473

(51) Int. Cl. H03K 23/00; G09G 3/34

(52) U.S. Cl. 345/84; 377/39; 377/2

(57) ABSTRACT

According to one embodiment, a backlight control apparatus includes a setting section which sets a count value according to a cycle of a PWM pulse signal, a counter section which counts to the count value set by the setting section, a comparing/changing section which compares an actually measured count value of the counter section at a timing of a given vertical synchronous signal with a set count value set according to the cycle of the PWM pulse signal so as to change the count value according to the compared result, a determining section which generates a histogram of a given video signal so as to determine a duty ratio based on the histogram, and a PWM pulse signal generating section which generates a PWM pulse signal based on the counted result from the counter section and the duty ratio determined by the determining section.

### CROSS-REFERENCE TO RELATED APPLICATIONS

This application is based upon and claims the benefit of priority from Japanese Patent Application No. 2006-324473, filed Nov. 30, 2006, the entire contents of which are incorporated herein by reference.

### BACKGROUND

1. Field

One embodiment of the invention relates to a backlight control apparatus for a backlight section of a flat panel display device, a display device, and a method for controlling a backlight of the display device.

2. Description of the Related Art

Recently, plane display devices such as liquid crystal display devices, EL displays and plasma displays have been widely developed and used. Liquid crystal display devices have a backlight section which irradiates back surfaces of display elements. The irradiation by means of the back light section is not always carried out with luminance of 100%, and thus the luminance of the irradiation is occasionally changed according to luminance of video signals.

In Patent Document 1 (Jpn. Pat. Appln. KOKAI Publication No. 2004-126567), a plurality of basic signals for modulating a pulse width are generated, the pulse width of a first basic signal is modulated by a dimming signal, so that a lamp drive signal having high section and low section is generated. Every time a pulse of a vertical synchronous signal is generated, turning-on time of the lamp drive signal is controlled, and a second basic signal is controlled so as to be synchronous with a horizontal synchronous signal. A predetermined standard voltage is compared with the second basic signal so that oscillation timing is provided.

The conventional technique in Patent Document 1 cannot cope with a fluctuation of the backlight described below. That is to say, a system, which obtains a luminance histogram of an input image and outputs PWM (Pulse Width Modulation) according to the result of the histogram so as to control the backlight of a panel, has the following problem. In the case where a vertical synchronous signal of the panel transiently fluctuates at the time of outputting PWM synchronous with the vertical synchronous signal (Vsync) of the panel, the backlight fluctuates due to excessive PWM output (high period).

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a block diagram illustrating one example of a constitution of a display device including a backlight control section according to one embodiment of the present invention;

FIG. 2 is an outline view illustrating one example of an outline of the constitution of the display device including the backlight control section according to one embodiment of the present invention;

FIG. 3 is a block diagram illustrating one example of the constitution for a basic operation of the backlight control section according to one embodiment of the present invention;

FIG. 4 is a timing chart illustrating one example of an operation of the backlight control section according to one embodiment of the present invention; and

FIG. 5 is a flow chart illustrating one example of a PLL process of the backlight control section according to one embodiment of the present invention.

### DETAILED DESCRIPTION

Various embodiments according to the invention will be described hereinafter with reference to the accompanying drawings. In general, according to one embodiment of the invention, a backlight control apparatus comprising: a setting section which sets a count value according to a cycle of a PWM pulse signal; a counter section which counts to the count value set by the setting section; a comparing/changing section which compares an actually measured count value of the counter section at a timing of a given vertical synchronous signal with a set count value set according to the cycle of the PWM pulse signal so as to change the count value according to the compared result; a determining section which generates a histogram of a given video signal so as to determine a duty ratio based on the histogram; and a PWM pulse signal generating section which generates a PWM pulse signal based on the counted result from the counter section and the duty ratio determined by the determining section.

An embodiment of the present invention will be described in detail below with reference to the drawings.

### Outline of One Embodiment of the Present Invention

One embodiment of the present invention provides a function for monitoring a PWM cycle, feeding back a read value, forming PLL (Phase Lock Loop) by means of a software process, and making a control so that the PWM cycle accurately falls within a vertical synchronous signal period to be supplied to the panel. One embodiment also provides a function for masking an excessive PWM output period. As a result, even if the vertical synchronous signal fluctuates, a control can be made so that the backlight does not fluctuate.

1. A system acquires a histogram of an input image, synchronizes PWM according to the result with a vertical synchronous signal of a panel, and outputs it so as to control a backlight.

2. A PLL system calculates a shift amount between the PWM cycle and the vertical synchronous signal according to a counted number of the PWM cycle obtained at the timing of the vertical synchronous signal, and reflects the result in the PWM cycle.

3. A system creates a pulse which is high only for a period of the PWM cycle to be output between the vertical synchronous signals, and masks a pulse for the other period. As a result, even if the PWM cycle is controlled by PLL so as to fall between the vertical synchronous signals of the panel, an error is generated during the PLL control. An influence of the error is eliminated by this system.

### One Example of Display Device Including Backlight Control Section According to One Embodiment of the Present Invention

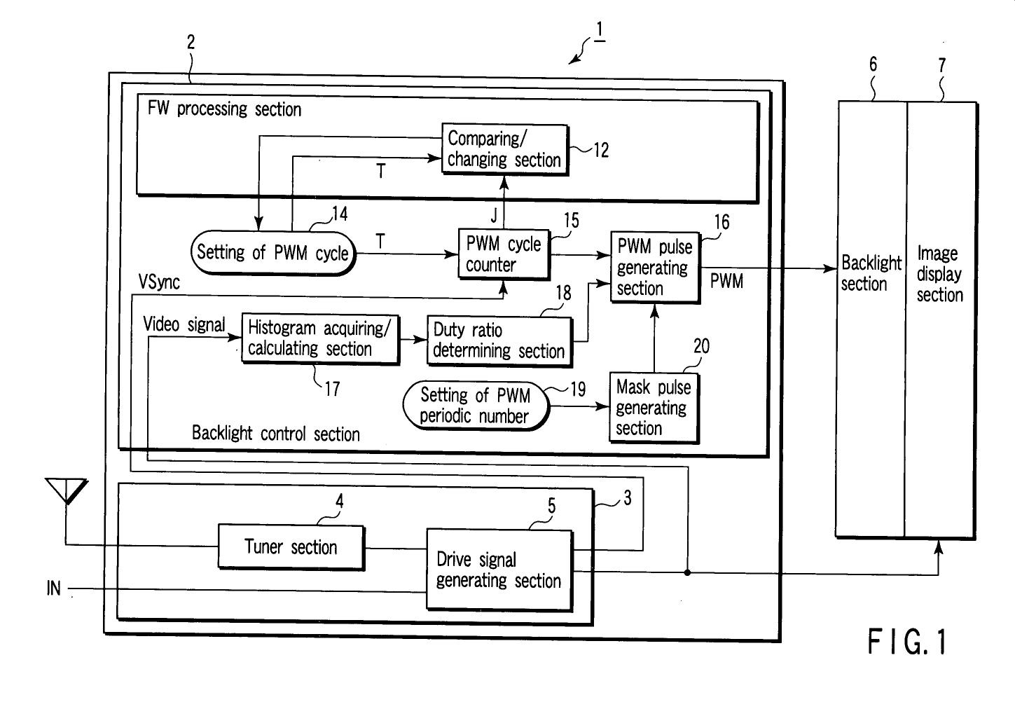

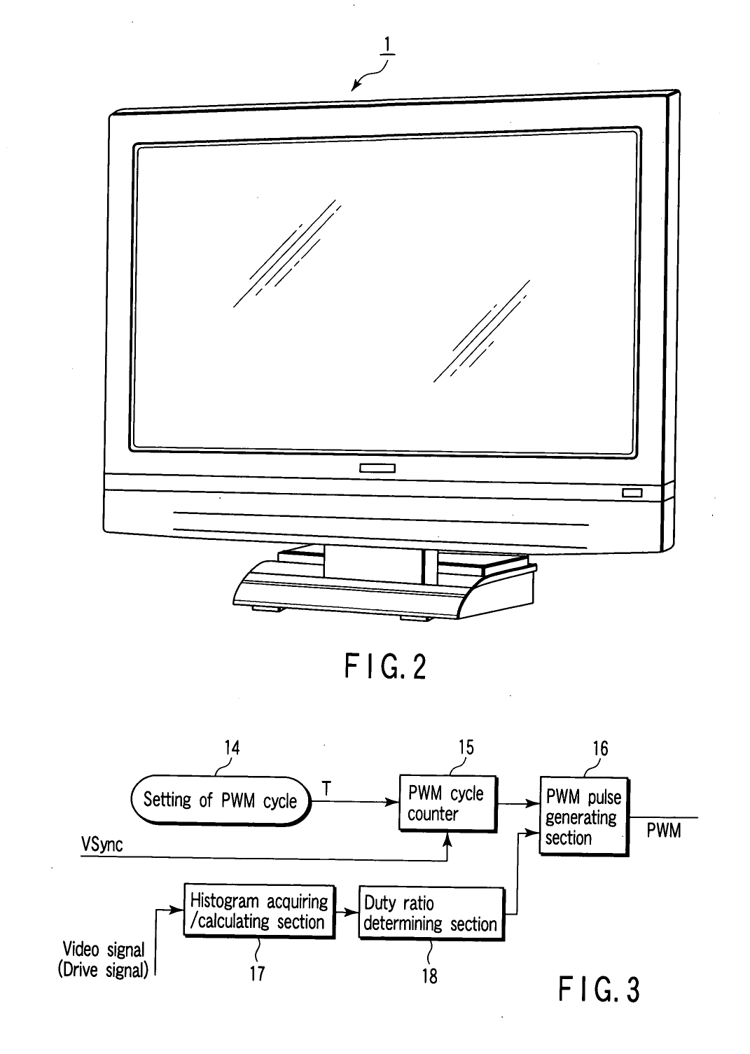

FIG. 1 is a block diagram illustrating one example of a constitution of a display device including a backlight control section according to one embodiment of the present invention. FIG. 2 is an outline view illustrating one example of an outline of the constitution of the display device including the backlight control section according to one embodiment of the present invention. FIG. 3 is a block diagram illustrating one example of a constitution for a basic operation of the backlight control section according to one embodiment of the present invention.

A display device 1 including the backlight control section according to one embodiment of the present invention has the outline shown in FIG. 2. In the constitution shown in FIG. 1, the display device 1 has a backlight control section 2, a receiver section 3, a liquid crystal display section 7, and a backlight section 6 which irradiates the back of the liquid crystal display section 7. A light quantity is controlled by a PWM signal according to a duty ratio so that the backlight section 6 is driven as mentioned later.

The receiver section 3 has a tuner section 4 such as a digital ground wave tuner, a digital BS tuner or a digital CS tuner, and a drive signal generating section 5. The drive signal generating section 5 receives a video/audio signal from the tuner section 4 or the outside, executes various types of video signal processes, and generates a drive signal (video signal, vertical synchronous signal or horizontal synchronous signal) for driving flat panel image elements of the image display section 7.

The backlight control section 2 has a histogram calculating section 17, and a duty ratio determining section 18. The histogram calculating section 17 acquires and calculates a histogram from a vertical synchronous signal and a video signal to be supplied from the drive signal generating section 5 of the receiver section 3. The duty ratio determining section 18 determines a duty ratio of a PWM pulse signal based on the histogram calculated result from the histogram calculating section 17. The backlight control section 2 has a PWM cycle setting section 14, and a PWM cycle counter 15. The PWM cycle setting section 14 sets a set value (for example, 500,000 count) of the PWM cycle to be supplied from the outside (IIC register) to the circuit. The PWM cycle counter 15 counts a clock (for example, 150 MHz) at start timing of the vertical synchronous signal to be supplied from the drive signal generating section 3 so as to create a cycle of the PWM pulse signal.

The backlight control section 2 has a PWM pulse generating section 16 which generates the PWM pulse signal based on the cycle of the PWM pulse signal from the PWM cycle counter 15 and the duty ratio from the duty ratio determining section 18. The backlight control section 2 has a PWM periodic number setting section 19 and a mask pulse generating section 20 as the constitution for executing the mask process. The mask pulse generating section 20 generates a mask pulse, mentioned later, based on the PWM periodic number and the counted result from the PWM cycle counter section 15. A mask pulse output is supplied to the PWM pulse generating section 16.

(Basic Operation)

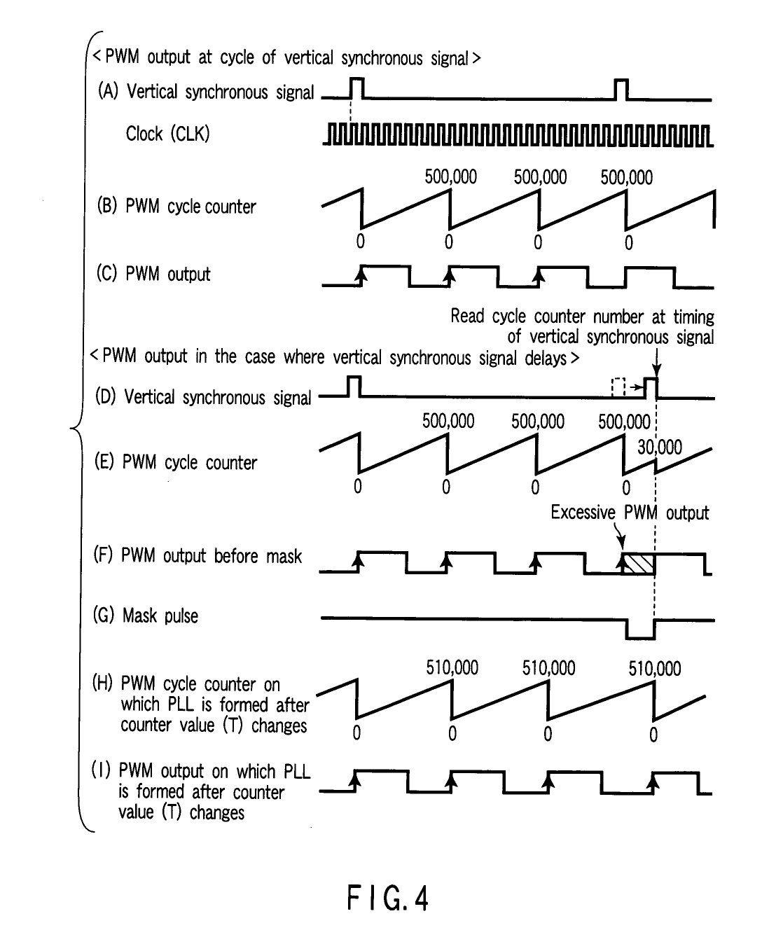

The basic operation of the backlight control section 2 will be described by using the constitution shown in FIG. 3 and the timing chart in FIG. 4. FIG. 4 is a timing chart illustrating one example of the operation of the backlight control section according to one embodiment of the present invention.

In a main section shown in FIG. 3 of the backlight control section 2, a vertical synchronous signal is supplied from the drive signal generating section 5 of the receiver section 3. This vertical synchronous signal is supplied as a synchronous signal of 100 Hz or the like (100 times per second) like a vertical synchronous signal (A) of FIG. 4. The PWM cycle setting section 14 sets a set count value (T) as 500,000 counts. A clock for controlling the counter has a frequency of 150 MHz, for example.

The PWM cycle counter 15 counts to 500,000 as one example, as shown in (B) of FIG. 4. In the PWM pulse generating section 16, the PWM output can be obtained three times per cycle of the vertical synchronous signal according to the counted results of the PWM cycle counter 15.

On the other hand, the duty ratio determining section 18 determines a duty ratio according to the histogram calculated result from the histogram acquiring/calculating section 17, and the duty ratio is supplied to the PWM pulse generating section 16. The duty ratio shows a value of about 60% like (C) in FIG. 4, and the PWM pulse signal having such a duty ratio is generated by the PWM pulse generating section 16 so as to be supplied to a later stage.

After receiving this PWM pulse signal, the backlight section 6 irradiates the image display section 7 with backlight with output of about 60%. That is to say, when the output of the backlight is not set to 100%, a power saving effect can be improved, and the backlight which is repressed according to the luminance of an image at that time is provided.

<Adjusting Process for PWM Pulse when Vertical Synchronous Signal Fluctuates>

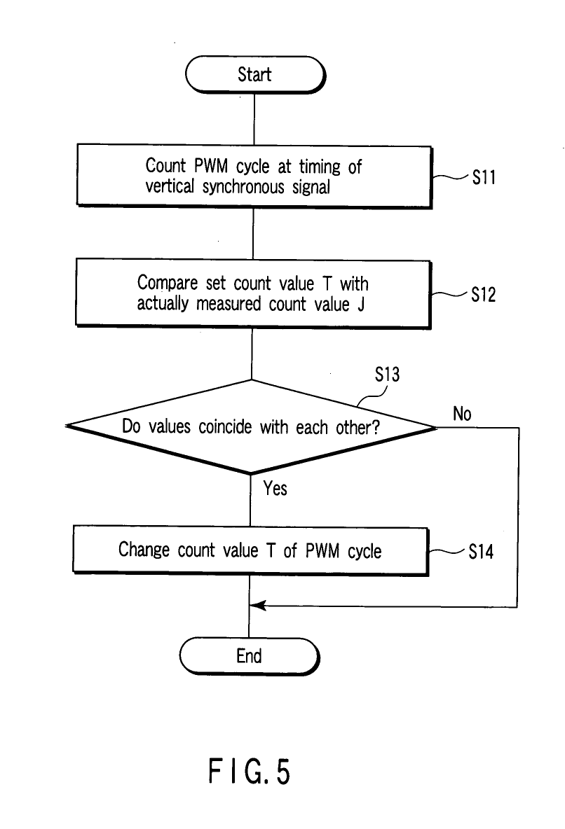

The adjusting process for the PWM pulse signal at the time when the vertical synchronous signal fluctuates will be described in detail below with reference to the timing chart of FIG. 4 and the flow chart of FIG. 5.

That is to say, in the constitution of the backlight control section 2 shown in FIG. 1, a vertical synchronous signal is supplied from the drive signal generating section 5 of the receiver section 3. This vertical synchronous signal is supplied as a synchronous signal of 100 Hz (100 times per second), for example, like the vertical synchronous signal (A) in FIG. 4. A delay of 2%, for example, occurs due to a noise like a vertical synchronous signal (D) in FIG. 4.

On the other hand, the PWM cycle setting section 14 sets a set count value (T) as 500,000 counts. A clock for controlling the counter has a frequency of 150 MHz, for example.

The PWM cycle counter 15 counts to, for example, 500,000 like the vertical synchronous signal (E) in FIG. 4. Since a delay of 2% occurs like a vertical synchronous signal (D) in FIG. 4, the counted result of the PWM cycle counter 15 is 500,000+500,000+500,000+30,000 like (E) in FIG. 4. Therefore, for example, an actual measured count value (J) indicates 30,000 counts when the vertical synchronous signal is high.

As a result, the PWM pulse signal generated by the PWM pulse generating section 16 shows a waveform like (F) in FIG. 4, so that an excessive PWM output is attached to the last. As a result, although the duty ratio determining section 18 sets the duty ratio of about 60% in the PWM pulse generating section 16, the final PWM pulse within the vertical synchronous signal period has the duty ratio of about 56%, for example. This appears as an inadequate control result of the backlight section 6.

In this embodiment, a comparing/changing section 12 of the FW processing section eliminates this fluctuation in the following manner. The function of the comparing/changing section 12 can be obtained as the constitution composed of a microcomputer and a program but is not limited to this. As shown in the flow chart of FIG. 5, the PWM cycle counter 15 starts the count from the timing of the vertical synchronous signal (step S11). The count value of, for example, 30,000 is obtained as an actually measured count value (J) at the timing of the vertical synchronous signal.

The actually measured count value (J), the set count value (T) set by the PWM cycle setting section 14 and the set count value (T) corresponding to 500,000 are compared (step S12).

When the actually measured count value (J) does not coincide with the set count value (T) (step S13), the set count value (T) is changed into, for example, 510,000 counts or the like according to a difference between the actually measured count value (J) and the set count value (T) (step S14).

As a result, the PWM pulse generating section 16 can obtain uniform counted results as the output like (H) in FIG. 4. The PWM pulse generating section 16, therefore, can output a PWM pulse signal in which the duty ratio of about 60% set as one example by the duty ratio determining section 18 is reflected without fluctuation like (I) in FIG. 4.

(Mask Process)

It is desirable that the constitutions of the PWM periodic number setting section 19 and the mask pulse generating section 20 shown in FIG. 1 mask an excessive PWM output shown in (F) of FIG. 4 during the feedback process. As a result, an influence of the excessive PWM output just after the fluctuation of the vertical synchronous signal can be avoided.

A mask pulse shown in (G) of FIG. 4 is generated by the mask pulse generating section 20 based on the counted results from the PWM periodic number setting section 19 and the PWM cycle counter section 15. Three as the PWM periodic number (n) from the PWM periodic number setting section 19, the PWM periodic number, 500,000 as the count value (T) from the PWM cycle counter section 15 are given, and the mask pulse becomes active for a period of 500,000×3=1500,000 counts. Thereafter, the mask pulse becomes inactive, and during the inactive period, the mask process is executed.

That is to say, the mask pulse generating section 20 obtains a shift between the set timing of the vertical synchronous signal and the detected timing of the vertical synchronous signal. A signal for an excessive period in the PWM pulse signal (F) to be output from the PWM pulse signal generating section 16 can be masked.

A person skilled in the art can realize the present invention by the above various embodiments, and easily conceives of various modified examples of these embodiments, and can apply the present invention to various embodiments without inventive ability. The present invention, therefore, covers a wide range which does not conflict with the disclosed principle and new characteristics, and thus is not limited to the above embodiments.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A backlight control apparatus comprising:
a setting section which sets a count value according to a cycle of a PWM pulse signal;
a counter section which counts to the count value set by the setting section;
a comparing/changing section which compares an actually measured count value of the counter section at a timing of a given vertical synchronous signal with a set count value set according to the cycle of the PWM pulse signal so as to change the count value according to the compared result;
a determining section which generates a histogram of a given video signal so as to determine a duty ratio based on the histogram; and
a PWM pulse signal generating section which generates a PWM pulse signal based on the counted result from the counter section and the duty ratio determined by the determining section.

2. The backlight control apparatus according to claim 1, wherein the comparing/changing section compares the actually measured count value from the counter section with the set count value set according to the cycle of the PWM pulse signal so as to obtain a difference therebetween and changes the count value according to the difference.

3. The backlight control apparatus according to claim 1, further comprising:
a mask section which obtains a shift between a set cycle of a vertical synchronous signal and a cycle of a vertical synchronous signal from a drive signal generating section so as to mask a signal for an excessive period in the PWM pulse signal to be output from the PWM pulse signal generating section.

4. The backlight control apparatus according to claim 3, wherein a setting section, which sets a PWM cyclic number within a vertical synchronous signal period of the count value set by the setting section, specifies an excessive period of the PWM pulse signal generated by the PWM pulse signal generating section.

5. A display device comprising:
a drive signal generating section which generates a video signal, a vertical synchronous signal and a horizontal synchronous signal for driving a flat panel image element based on a signal supplied from the outside;
an image display section which receives the video signal, the vertical synchronous signal and the horizontal synchronous signal from the drive signal generating section so as to display an image on the flat panel image element accordingly;
a backlight control section including: a setting section which sets a count value according to a cycle of a PWM pulse signal; a counter section which counts to the count value set by the setting section; a comparing/changing section which compares an actually measured count value of the counter section at a timing of the vertical synchronous signal from the drive signal generating section with a set count value set according to the cycle of the PWM pulse signal so as to change the count value according to the compared result; a determining section which generates a histogram of a video signal from the drive signal generating section so as to determine a duty ratio based on the histogram; and a PWM pulse signal generating section which outputs a PWM pulse signal based on the counted result from the counter section and the duty ratio determined by the determining section; and
a backlight section which receives the PWM pulse signal from the backlight control section so as to irradiate the image display section accordingly.

6. The display device according to claim 5, wherein the comparing/changing section compares the actually measured count value from the counter section with the set count value set according to the cycle of the PWM pulse signal so as to obtain a difference therebetween and changes the count value according to the difference.

7. The display device according to claim 5, further comprising:
a mask section which obtains a shift between set timing of a vertical synchronous signal and timing of a vertical synchronous signal from the drive signal generating section so as to mask a signal for an excessive period in the PWM pulse signal to be output from the PWM pulse signal generating section.

8. The display device according to claim 5, wherein the count value set by the setting section is compared with an actually measured count value obtained by the counter section, so that an excessive period of the PWM pulse signal generated by the PWM pulse signal generating section is specified.

9. A backlight control method for controlling a backlight section which irradiates a back of a display surface having a flat panel image element in a display device which generates a drive signal based on a signal supplied from the outside and displays an image on the flat panel image element, the method comprising:
setting a count value according to a cycle of a PWM pulse signal;
counting to the set count value at a start timing of a vertical synchronous signal from a drive signal generating section;
obtaining an actually measured count value at a detected timing of the vertical synchronous signal;
comparing the actually measured count value with the set count value set according to the cycle of the PWM pulse signal so as to change the count value according to the compared result;
generating a histogram of a video signal so as to determine a duty ratio based on the histogram; and
outputting a PWM pulse signal based on the counted result and the determined duty ratio so as to control the backlight section according to the PWM pulse signal.

10. The backlight control method according to claim 9, further comprising:
masking a signal for an excessive period in the PWM pulse signal according to the set count value of the PWM cycle and a mask pulse generated based on a set value of a PWM periodic number.
